(19) United States
(12) Patent Application Publication
(10) Pub. No.: US 2025/0338488 A1
(43) Pub. Date: Oct. 30, 2025

(54) SEMICONDUCTOR DEVICE

(71) Applicant: Fujian Jinhua Integrated Circuit Co., Ltd., Quanzhou City (CN)

(72) Inventors: Yu-Cheng Tung, Quanzhou City (CN); Janbo Zhang, Quanzhou City (CN)

(73) Assignee: Fujian Jinhua Integrated Circuit Co., Ltd., Quanzhou City (CN)

(21) Appl. No.: 18/822,268

(22) Filed: Sep. 1, 2024

(30) Foreign Application Priority Data
Apr. 30, 2024 (CN) 202410543708.5

(51) Int. Cl. H10B 12/00

(52) U.S. Cl. CPC H10B 12/50; H10B 12/09; H10B 12/315

(57) ABSTRACT

A semiconductor device includes a substrate, a gate structure, insulating spacers, first pads, an insulating layer and a high dielectric constant dielectric layer. The insulating spacers and the gate structures are alternately disposed on the substrate. The first pads are disposed on the insulating spacers. The insulating layer overlies the insulating spacers and the gate structure, wherein a portion of the insulating layer overlying the gate structure has a recess. The high dielectric constant dielectric layer is disposed in the recess, and a bottommost surface of the high dielectric constant dielectric layer is lower than a topmost surface of the first pads. By disposing the high dielectric constant dielectric layer and/or the insulating layer, defects can be prevented from occurring in the top structures of the gate structures, and short-circuit problems can be avoided from occurring between the gate structure and the metal interconnection line disposed thereabove.

### BACKGROUND OF THE INVENTION

### 1. Field of the Invention

The present invention generally relates to a semiconductor device, and more particularly, to a semiconductor device including gate structures.

### 2. Description of the Prior Art

With the trend of miniaturization of various electronic products, the design of semiconductor devices must also meet the requirements of high integration and high density. For dynamic random access memories (DRAMs) having recessed gate structures, current leakage of capacitor structures can be reduced due to longer carrier channel length in the same semiconductor substrate. Therefore, under the current mainstream of development trend, they have gradually replaced the DRAMs having only planar gate structures. In general, a DRAM with a recessed gate structure includes a huge number of memory cells, which form an array region for storing data. Each of the memory cells includes a transistor component and a capacitor component connected in series to receive voltage signals from bit lines and word lines. To meet the demands on features of products, it is still necessary to keep raising the intensity of the memory cells in the array region. As a result, the manufacturing process and the design would become more and more critical, and the complexity would be higher and higher. Therefore, the prior art techniques or the conventional structures need to be further improved to effectively improve the performance and reliability of related memory devices.

### SUMMARY OF THE INVENTION

An object of the present invention is to provide a semiconductor device, which includes a high dielectric constant dielectric layer having a recess or a pad spacer having a lower surface additionally disposed on the gate structure to cover and protect the gate structure. Accordingly, defects can be prevented from occurring in the top structures of the gate structures, and short-circuit problems can be avoided from occurring between the gate structure and the metal interconnection line disposed thereabove.

In order to achieve the above objects, an embodiment of the present invention provides a semiconductor device, which includes a substrate, a gate structure, insulating spacers, first pads, an insulating layer and a high dielectric constant dielectric layer. The gate structure is disposed on the substrate. The insulating spacers and the gate structure are alternately disposed on the substrate. The first pads are disposed on the insulating spacers. The insulating layer overlies the insulating spacers and the gate structure, wherein a portion of the insulating layer overlying the gate structure has a recess. The high dielectric constant dielectric layer is disposed in the recess, and a bottommost surface of the high dielectric constant dielectric layer is lower than a topmost surface of the first pads.

In order to achieve the above objects, another embodiment of the present invention provides a semiconductor device, which includes a substrate, a gate structure, insulating spacers, a first spacer structure, first pads and first pads. The substrate is defined with a first region and a second region. The gate structure is disposed on the substrate and located in the first region. The first spacer structure is disposed on a sidewall of the gate structure. The insulating spacers and the gate structure are alternately disposed on the substrate and located in the first region. The first pads are disposed on the insulating spacers in the first region, respectively. The pad spacers are disposed on sidewalls of the plurality of first pads in the first region, respectively. A bottom surface of the pad spacers is lower than a top surface of the first spacer structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 is a cross-sectional view schematically illustrating a semiconductor device according to a first embodiment of the present application.

FIG. 2 to FIG. 7 are schematic diagrams illustrating a method of forming the semiconductor device according to a preferred embodiment of the present invention, wherein:

FIG. 2 is a cross-sectional view schematically illustrating an intermediate of the semiconductor device after plug holes are formed;

FIG. 3 is a cross-sectional view schematically illustrating an intermediate of the semiconductor device after a metal material layer is formed;

FIG. 4 is a cross-sectional view schematically illustrating an intermediate of the semiconductor device after pads are formed;

FIG. 5 is a cross-sectional view schematically illustrating an intermediate of the semiconductor device after a first dielectric material layer is formed;

FIG. 6 is a cross-sectional view schematically illustrating an intermediate of the semiconductor device after a second dielectric material layer is formed; and

FIG. 7 is a cross-sectional view schematically illustrating an intermediate of the semiconductor device after a capacitive dielectric layer is formed.

FIG. 8 is a cross-sectional view schematically illustrating a semiconductor device according to a second embodiment of the present application.

FIG. 9 is a cross-sectional view schematically illustrating a semiconductor device according to a third embodiment of the present application.

### DETAILED DESCRIPTION

For better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

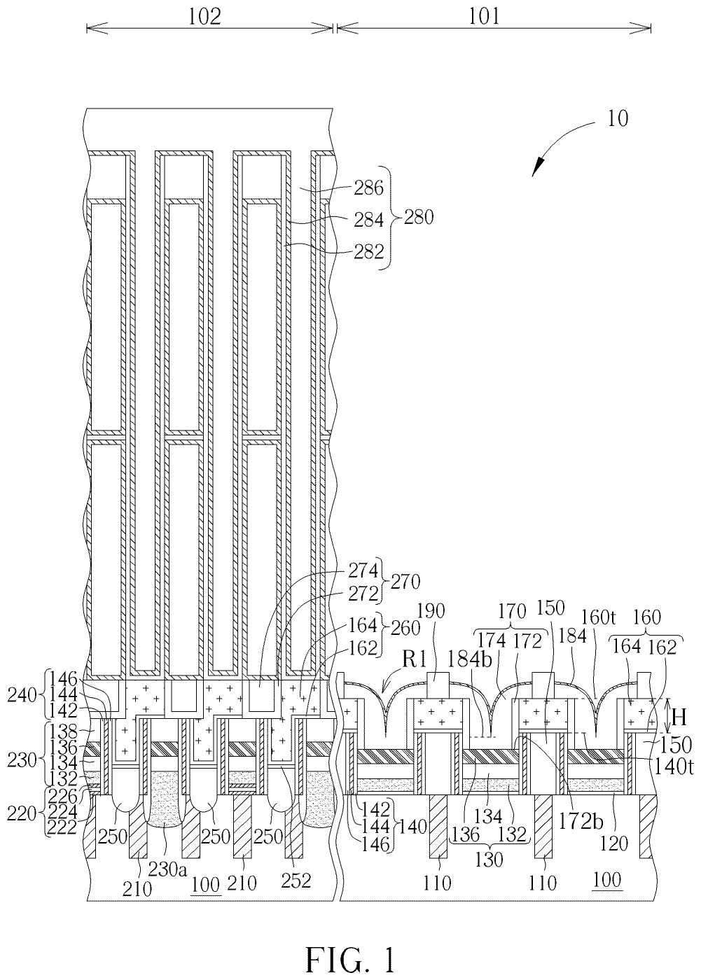

Please refer to FIG. 1, which is a cross-sectional view schematically illustrating a semiconductor device according to a first embodiment of the present application. As shown in FIG. 1, the semiconductor device 10 includes a substrate 100, gate structures 130, a plurality of insulation spacers 150, a plurality of first pads 160, an insulating layer 170, and a high dielectric constant material layer 184. The substrate 100 may be, for example, but not limited to, a silicon substrate, a silicon-containing substrate, an epitaxial silicon substrate, a silicon-on-insulator (SOI) substrate, or a substrate formed of any other suitable material. In an embodiment, the substrate 100 further includes a first region 101, e.g., a peripheral region of the semiconductor device 10, where the component integration level is relatively low, and a second region 102, e.g., a cell region of the semiconductor device 10, where the component integration level is relatively high. The first region 101 and the second region 102 are disposed adjacent to each other, for example but not limited thereto. Furthermore, a plurality of shallow trench isolations (STI) 110 and 120 are disposed in the first region 101 and the second region 102 of the substrate 100, and a plurality of active areas (AA, not shown) are defined in the substrate 100.

The gate structures 130 and the insulation spacers 150 are disposed on the substrate 100 and located in the first region 101, wherein two of the insulation spacers 150 are disposed at opposite sides of a corresponding one of the gate structures 130. The first pads 160 are disposed on the insulation spacers 150 and covered by the insulating layer 170 from top. The insulating layer 170 also overlies the gate structures 130. The high dielectric constant material layer 184 further overlies the insulating layer 170. It is to be noted that the insulating layer 170 overlying the gate structures 130 has recesses R1 so that the high dielectric constant material layer 184 is partially disposed in the recesses R1, and the bottommost surfaces 184b of the high dielectric constant material layer 184 are lower than the topmost surfaces 160t of the first pads 160. Accordingly, the top structures of the gate structures 130 having a relatively wide line width can be protected by being sequentially covered by the insulating layer 170 and the high dielectric constant material layer 184. As such, the first pads 160 can be isolated from physical contact with the gate structures 130, so as to avoid possible short-circuit problems occurring in metal interconnection lines disposed on the first pads 160, for example, the contact structures 190.

In an embodiment, for example, the first pads 160 have a height H in a direction perpendicular to the substrate 100 (not shown). The bottommost surfaces 184b of the high dielectric constant material layer 184 are preferably at a position lowered than a middle position of the high dielectric constant material layer 184, e.g., 1/2H down from the topmost surfaces 160t of the first pads 160, thereby ensuring that the high dielectric constant material layer 184 completely and effectively overlies the first pads 160 and the gate structure 130 and avoiding direct contact therebetween. The semiconductor device 10 further includes a dielectric layer 120 disposed at the bottom of one of the gate structures 130 and first spacer structures 140 disposed at opposite sidewalls of the gate structure 130. The dielectric layer 120, for example, includes an insulating material such as silicon oxide, and functions as a gate dielectric layer of the gate structure 130. Each of the first spacer structures 140 is disposed between the gate structure 130 and a corresponding one of the insulation spacers 150 and functions as a gate spacer structure of the gate structure 130. Preferably, Top surfaces 140t of the first spacer structures 140 are higher than a top surface of the gate structure 130 in order to effectively insulate the gate structure 130 and the corresponding first pads 160. In an embodiment, the insulating layer 170 further includes a plurality of pad spacers 172 and a covering layer 174. For example, two of the pad spacers 172 are disposed on opposite sidewalls of a corresponding one of the first pads 160. Meanwhile, the pad spacers 172 overlie upper sidewalls of the first spacer structures 140, respectively. The covering layer 174 conformally overlies the pad spacers 172 and the first pads 160 in a manner that the insulating layer 170 includes the recesses R1 between adjacent pad spacers 172. The configuration is not limited to this. Furthermore, a plurality of contact structures 190 are disposed on the first pads 160, and include, for example, a low-resistivity metal material such as aluminum (Al), copper (Cu) or tungsten (W), serving as a first layer of metal interconnection lines of the semiconductor device 10, which are electrically connected to other conductive structures subsequently disposed on the semiconductor device 10.

Furthermore, the semiconductor device 10 includes a plurality of bit lines 230, a plurality of plugs 250, a plurality of second pads 260 and capacitor structures 280, which are disposed in the second region 102. The bit lines 230 and the plugs 250 are arranged alternately on the substrate 100, and second spacer structures 240 are disposed between the bit lines 230 and the plugs 250. In an embodiment, the process of forming the bit lines 230 may be integrated with the process of forming the gate structures 130 in the first region 101. Accordingly, each of the bit lines 230 and the gate structures 130 includes, sequentially from bottom to top, a stack of semiconductor layer 132, a barrier layer 134 and a metal layer 136, wherein the metal layer 136 in the bit lines 230 is further disposed thereon a cap layer 138. The semiconductor layer 132 includes, for example, a semiconductor material such as doped polysilicon or doped amorphous silicon. The barrier layer 134 includes, for example, a conductive barrier material such as titanium and/or titanium nitride (TiN), tantalum (Ta) and/or tantalum oxide. The metal layer 136 includes, for example, copper, aluminum, tungsten or other suitable conductive materials with low resistivity. The cap layer 138 includes, for example, an insulating material such as silicon oxide, silicon nitride or silicon oxynitride. The materials are not limited to the above examples. The bit lines 230 are basically arranged on the dielectric layer 220, and extend into the substrate 100 through corresponding bit line contacts (BLC) 230a formed thereunder to be electrically connected to the corresponding active areas. In an embodiment, the dielectric layer 220 includes, for example, a silicon oxide layer 222, a silicon nitride layer 224 and a silicon oxide layer 226 stacked in sequence to result in an oxide-nitride-oxide (ONO) structure, but it is not limited thereto. In another embodiment, a process of forming the second spacer structures 240 may also be integrated with the process of the first spacer structure 140 located in the first region 101, so that each of the first spacer structures 140 and the second spacer structures 240 includes a first spacer 142, a second spacer 144 and a third spacer 146 sequentially arranged on the sidewall of the gate structure 130 and the sidewall of the bit line 230 in a horizontal direction. Top surfaces of the second spacer structures 240 are, for example, coplanar with top surfaces of the bit lines 230 and higher than the top surfaces 140t of the first spacer structures 140 located in the first region 101. The first spacer 142 and the third spacer 146, for example, include the same insulating material, such as silicon nitride and silicon carbonitride, while the second spacer 144, for example, includes an insulating material different from that of the first spacer 142 and the third spacer 146. It may be, but not limited to, silicon oxide and silicon oxynitride.

The plugs 250 includes, for example, an epitaxial material such as silicon (Si), silicon phosphorus (SiP), silicon germanium (SiGe), or germanium (Ge), and function as storage node (SN) contacts of the semiconductor device 10 to be in physical contact with the active areas. The second pads 260 are disposed above the plugs 250 as storage node (SN) pads of the semiconductor device 10, and the capacitor structures 280 are disposed on the second pads 260. In detail, adjacent two second pads 260 are isolated from each other by one insulating layer 270, and one metal silicide layer 252 is further disposed between one of the second pads 260 and a corresponding one of the plugs 250. The metal silicide layer 252 includes, for example, but not limited to, a metal silicide material such as cobalt disilicide (CoSi₂), titanium disilicide (TiSi₂) or nickel silicide (Ni₂Si). In an embodiment, a process of forming the second pads 260 is, for example, integrated with a process of forming the first pads 160 located in the first region 101, so that each of the second pads 260 and the first pads 160 includes a barrier layer 162 and a metal layer 164 stacked in sequence. The barrier layer 162 includes, for example, a conductive barrier material such as titanium and/or titanium nitride (TiN), tantalum (Ta) and/or tantalum oxide (TaN), and the metal layer 164 includes, for example, copper, aluminum, tungsten or other suitable low-resistivity conductive materials, but is not limited thereto.

In an embodiment, each insulating layer 270 further includes a first dielectric layer 272 and a second dielectric layer 274 stacked in sequence, wherein the first dielectric layer 272 and the second dielectric layer 274 may have the same or different insulating materials, which may be selected from, but not limited to, silicon oxide, silicon nitride, silicon oxynitride and silicon carbonitride, etc., and preferably include silicon nitride. Moreover, a process of forming the insulating layers 270 may also be integrated with a process of forming the insulating layer 170 located in the first region 101, so that the pad spacers 172 of the insulating layer 170 include the same material as the first dielectric layer 272, and the covering layer 174 of the insulating layer 170 includes the same material as the second dielectric layer 274, but it is not limited thereto. The capacitor structures 280 include bottom electrode layers 282, a capacitor dielectric layer 284 and top electrode layers 286, which are sequentially arranged, to form a plurality of vertically extending capacitors, serving as storage nodes (SN) of the semiconductor device 10 and being in physical contact with the SN pads disposed thereunder, i.e., the second pads 260. The bottom electrode layers 282 include, for example, titanium nitride. The top electrode layers 286 include, for example, a composite structure of titanium nitride and silicon germanium. The capacitor dielectric layer 284 includes, for example, but not limited to, a high dielectric constant dielectric material selected from a group of metal oxides, such as hafnium oxide (HfO₂), hafnium silicon oxide (HfSiO₄), hafnium silicon oxynitride (HfSiON), zinc oxide (ZrO₂), titanium oxide (TiO₂) and zirconia-alumina-zirconia (ZAZ), and preferably includes zirconia-alumina-zirconia. In a preferred embodiment, a process of forming the capacitor dielectric layer 284 may be integrated with the high dielectric constant material layers 184 located in the first region 101. For example, when the capacitor dielectric layer 284 is formed, the high dielectric constant material layer 184 is simultaneously formed in the first region 101, so that the capacitor dielectric layer 284 and the high dielectric constant material layer 184 include the same material.

In the above-described configuration, the capacitor and the transistor component (not shown) located in the second region 102 of the substrate 100 can form a minimum memory cell to receive voltage information from the bit line 130 and the word line (not shown), so that the semiconductor device 10 in this embodiment can form a dynamic random access memory (DRAM) device and achieve enhanced operational performance. In this embodiment of semiconductor device 10, the high dielectric constant material layer 184 and the insulating layer 170 disposed thereunder are additionally arranged on the gate structures 130 to cover and protect the top structures of the gate structures 130, so as to ensure that the metal interconnection lines disposed in the first region 101 are only electrically connected to the first pads 160 without being in direct contact with the gate structures 130. Accordingly, the possible short-circuit problems can be avoided. Furthermore, the process of forming the high dielectric constant material layer 184 and the insulating layer 170 in the first region 101 can be accomplished together with the process of forming the specified components in the second region 102. Therefore, no additional operation or process is required, and the semiconductor device 10 in this embodiment can be made with a more reliable structure and have satisfactory performance based on the simplified manufacturing process. Those skilled in the art should easily understand that the semiconductor device according to the present invention may have alternative forms without being limited to the foregoing as long as the resulting products meet practical requirements. Other embodiments or variations of the semiconductor device in the present application will be further described below. For simplification, the following descriptions mainly focus on the differences among embodiments, and will not repeat the similarities. In addition, the same components in various embodiments in the present application are labeled with the same reference numerals, so as to facilitate mutual comparison among various embodiments.

Referring to FIG. 1 again, in another embodiment, the semiconductor device 10 may optionally include a substrate 100, gate structures 130, insulation spacers 150, first spacer structures 140, first pads 160 and pad spacers 172. The gate structures 130 and the insulating spacers 150 are both located in the first region 101 and disposed on the substrate 100 in a manner that a plurality of the insulating spacers 150 are located on both sides of one of the gate structures 130. One of the first spacer structures 140 is disposed on the sidewall of a corresponding one of the gate structures 130 and interposed between the gate structure 130 and the insulating spacers 150. The first pads 160 are disposed on the insulating spacers 150, respectively. In particular, a plurality of the pad spacers 172 are respectively arranged on the sidewalls of the first pads 160 while overlying the upper sidewalls of the first spacer structures 140, respectively, in a manner that the bottom surfaces 172b of the pad spacers 172 are lower than the top surfaces 140t of the first spacer structures 140. Accordingly, physical contact between the first pads 160 and the gate structures 130 can be effectively blocked by respective pad spacers 172, so as to ensure that the subsequently formed metal interconnection lines, e.g., contact structures 190, are only electrically connected to the first pads 160 and do not contact the gate e structures 130, thereby avoiding possible short-circuit problems.

In order to make those skilled in the art easily understand the semiconductor device 10 according to the present invention, a manufacturing process of the semiconductor device 10 according to the present application will be further described hereinafter.

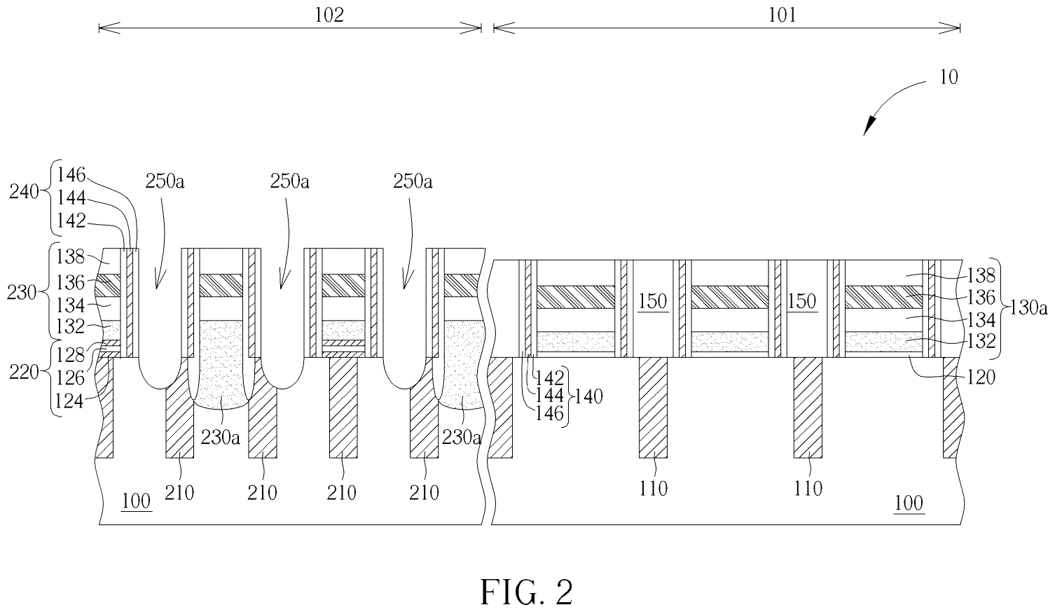

Please refer to FIGS. 2 to 7, which are schematic diagrams illustrating a manufacturing process of the semiconductor device 10 according to a preferred embodiment of the present application. First, as shown in FIG. 2, a substrate 100 is provided. Shallow trench isolations 110 and 210 are respectively formed in a first region 101 and a second region 102 of the substrate 100, and the active areas are respectively defined in the first region 101 and the second region 102. In an embodiment, the shallow trench isolations 110 and 210 are formed by, for example, performing an etching process to form a plurality of trenches (not shown) in the substrate 100, and then filling at least one insulating material, e.g., silicon oxide, silicon nitride, etc., in the trenches to form the shallow trench isolations 110 and 210 with surfaces flush with the top surface of the substrate 100, but not limited thereto.

Next, a plurality of buried word lines (not shown) are formed on the substrate 100 in the first region 101 and the second region 102. In one embodiment, a process of forming the buried word lines includes, but is not limited to, the following steps. For example, a plurality of trenches (not shown) that can pass through active areas and shallow trench isolations 210 at the same time are formed. Then, a dielectric layer (not shown) overlying the entire surface of the trenches, a gate dielectric layer (not shown) overlying the surface of the lower half portion of the trenches, a gate conductive layer (not shown) filling the lower half portion of the trenches, and a cap layer (not shown) filling the upper half portion of the trenches are formed in the trenches. Furthermore, a dielectric layer 120 and a dielectric layer 220 are formed on the substrate 100 in the first region 101 and the second region 102, respectively. In an embodiment, a process of forming the dielectric layer 120 and the dielectric layer 220 includes, but are not limited to, the following steps. For example, a dielectric material layer is formed on the substrate 100 in the first region 101 and the second region 102, and includes a first silicon oxide material layer (not shown), a silicon nitride material layer (not shown) and a second silicon oxide material layer (not shown) stacked in sequence. At least the second silicon oxide material layer and the silicon nitride material layer formed in the first region 101 of the substrate 100 are removed, so that the first silicon oxide material layer in the first region 101 of the substrate 100 forms the dielectric layer 120, and the dielectric material layer in the second region 102 of the substrate 100 forms the dielectric layer 220. Alternatively, in another embodiment, the dielectric material layer in the first region 101 of the substrate 100 can be completely removed, and then the dielectric layer 120 can be formed additionally.

Afterwards, a plurality of gate stacked structures 130a and a plurality of mutually spaced bit lines 230 are formed on the substrate 100 in the first region 101 and the second region 102 by a similar process. The gate stacked structures 130a have a relatively large line width compared with the bit lines 230, but it is not limited to thereto. In an embodiment, a process of forming the gate stacked structures 130a and the bit lines 230 includes, but is not limited to, the following steps. First, a plurality of openings (not shown) penetrating through the dielectric layer 220 and partially exposing the substrate 100 are formed in the second region 102, and a semiconductor material layer (not shown) formed of a semiconductor material including, for example, polysilicon or doped amorphous silicon is formed in the first region 101 and the second region 102 to fill the openings. Meanwhile, a barrier material layer (not shown) including a conductive barrier material, e.g., titanium and/or titanium nitride or tantalum and/or tantalum oxide, a metal material layer (not shown) including a metal material with low resistivity, e.g., tungsten, aluminum or copper, and a capping material layer (not shown) including an insulating material, e.g., silicon oxide, silicon nitride or silicon oxynitride, are formed on the semiconductor material layer. Afterwards, the gate stacked structures 130a, the bit lines 230 and bit line plugs 230a disposed under some of the bit lines 230 as shown in FIG. 2 are simultaneously formed through a patterning process. Accordingly, each of the gate stacked structures 130a and the bit lines 230 includes a semiconductor layer 132, a barrier layer 134, a metal layer 136 and a cap layer 138 sequentially stacked from bottom to top.

Referring to FIG. 2 again, first spacer structures 140 and second spacer structures 240 are formed by the same process, and each includes, for example, but not limited to, a first spacer 142 (including silicon nitride or silicon carbonitride, for example), a second spacer 144 (including silicon oxide or silicon oxynitride, for example) and a third spacer 146 (including silicon nitride or silicon carbonitride, for example) stacked in sequence in a horizontal direction. The stacks are formed on the sidewalls of the gate stack structures 130a and the bit lines 230.

Then, a deposition and etch-back process is performed to provide an insulating material between adjacent gate stack structures 130a and adjacent bit lines 230. The insulating material in the first region 101 forms insulating spacers 150. Subsequently, the insulating material between adjacent bit lines 230 is removed by using a mask layer (not shown), and a plurality of plug holes 250a partially exposing the substrate 100 are formed in the second region 102, as shown in FIG. 2. Afterwards, the mask layer is completely removed.

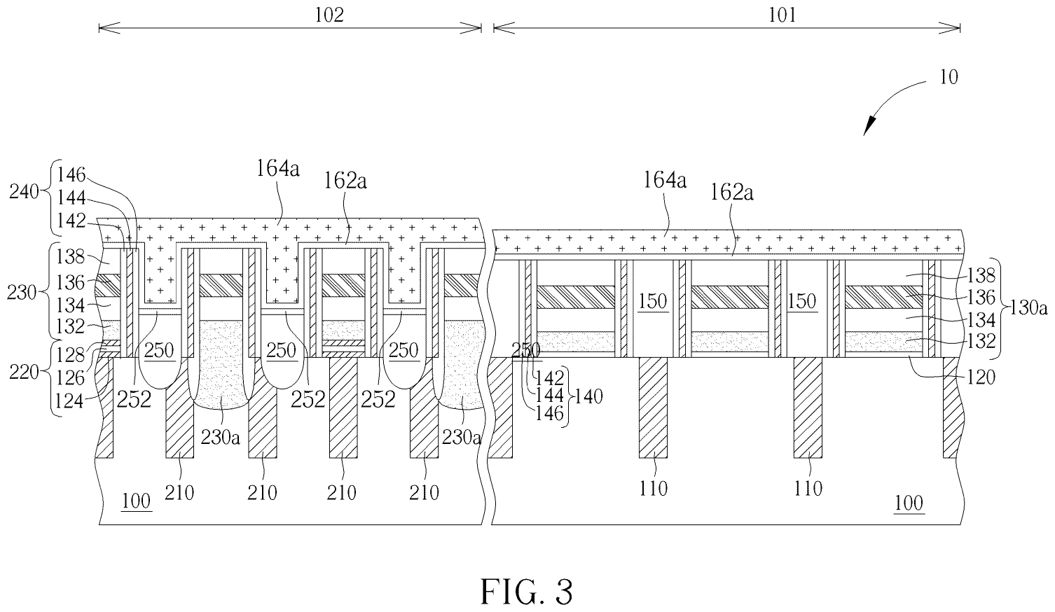

As shown in FIG. 3, an epitaxial forming process is performed to form plugs 250 in plug holes 250a in the second region 102, and a metal-silicide forming process is performed on the plugs 250 to form a metal silicide layer 252. In one embodiment, the plugs 250 include, for example, an epitaxial material such as silicon, silicon phosphorus, silicon germanium, or germanium. The metal silicide layer 252 includes, for example, but not limited to, a metal silicide material such as cobalt disilicide, titanium silicide, or nickel silicide. The plugs 250 formed in this way can be used as storage node plugs of the semiconductor device 10. Then, at least one deposition process is performed, and a barrier material layer 162a including, for example, titanium and/or titanium nitride or tantalum and/or tantalum oxide, and a metal material layer 164a including, for example, copper, aluminum, tungsten or any other suitable metal material with low resistivity, are simultaneously formed on the substrate 100 in the first region 101 and the second region 102. In the configuration, a part of the barrier material layer 162a is conformally formed in the plug holes 250a as shown in FIG. 2, and the other part of the barrier material layer 162a is formed outside the plug holes 250a. The remaining space of the plug holes 250a is filled by a portion of the metal material layer 164a.

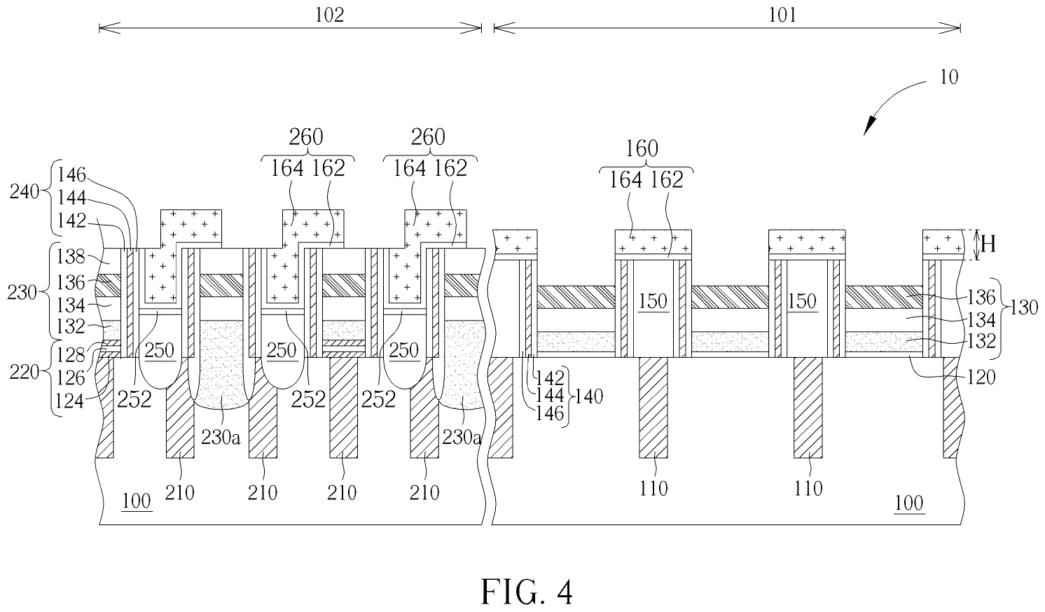

As shown in FIG. 4, the first pads 160 and the second pads 260 are formed on the substrate 100 in the first region 101 and the second region 102, respectively, by using another mask layer (not shown), and then the another mask layer is completely removed. The first pads 160, for example, have a height H in a direction perpendicular to the substrate 100, but it is not limited thereto. It is to be noted that the first pads 160 are formed on the insulating spacers 150 and the first spacer structures 140, and when the first pads 160 are formed, the capping layers 138 of the gate stack structures 130a are removed synchronously by adjusting the etching parameters. As a result, the gate structures 130 are formed. On the other hand, the second pads 260 are partially formed on the bit lines 230 and the second spacer structures 240, and partially formed in the plug holes 250a as shown in FIG. 2, which are in physical contact with the metal silicide layer 252 and electrically connected to the plugs 250. In this way, the second pads 260 can be formed as storage node pads of the semiconductor device 10.

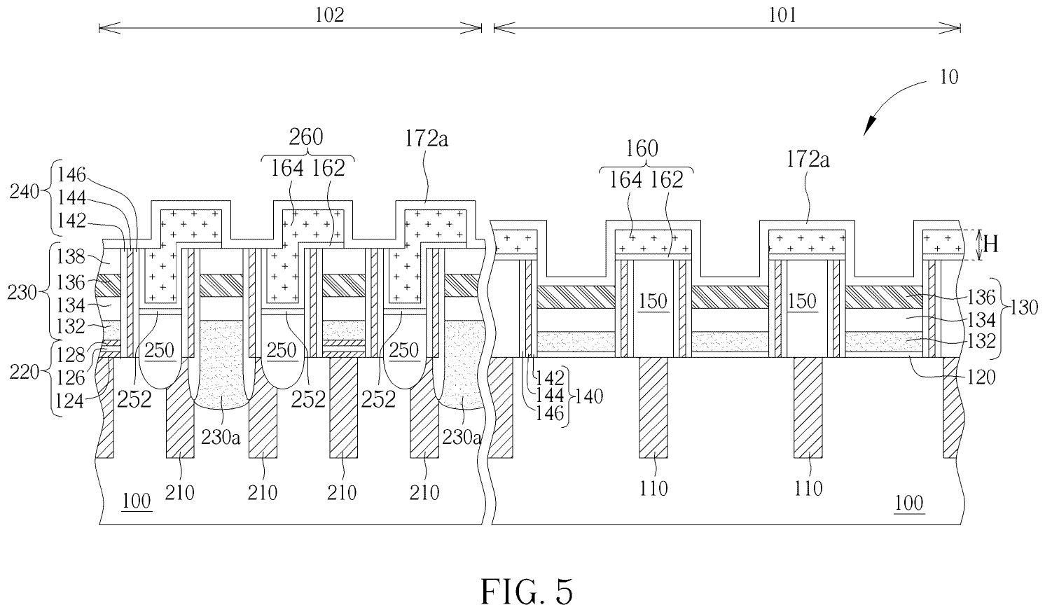

As shown in FIG. 5, a deposition process is performed to form a first dielectric material layer 172a on the substrate 100 in the first region 101 and the second region 102. The first dielectric material layer 172a includes, for example, an insulating material such as silicon oxide, silicon nitride, silicon oxynitride or silicon carbonitride. The first dielectric material layer 172a integrally covers the first pads 160, the first spacer structures 140 and the gate structures 130 in the first region 101, and also integrally covers the second pads 260, the second spacer structures 240 and the bit lines 230 in the second region 102.

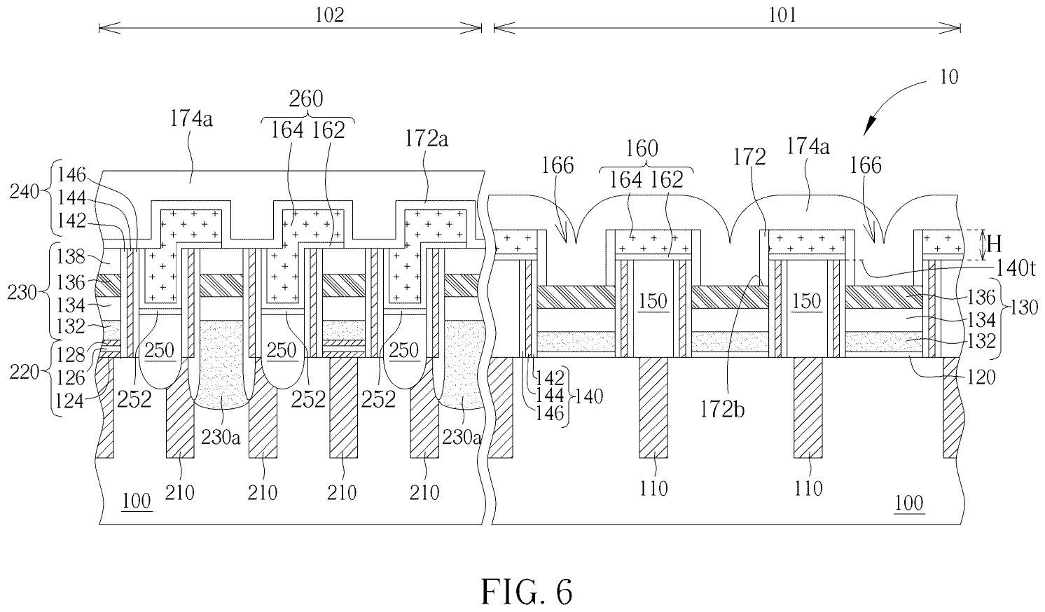

As shown in FIG. 6, the first dielectric material layer 172a formed in the first region 101 is partially removed by using another mask layer (not shown) to form pad spacers 172, and then the another mask layer is completely removed. The pad spacers 172 partially cover the sidewalls of the first pads 160 and partially cover the sidewalls of the upper half portions of the first spacer structures 140. In a preferred embodiment, the bottom surfaces 172b of the pad spacers 172 are lower than the top surfaces 140t of the first spacer structures 140, thus effectively blocking physical contact between the first pads 160 and the gate structures 130.

Then, another deposition process is performed to form a second dielectric material layer 174a on the substrate 100 in the first region 101 and the second region 102. The second dielectric material layer 174a includes, for example, an insulating material such as silicon oxide, silicon nitride, silicon oxynitride or silicon carbonitride. In this configuration, the second dielectric material layer 174a formed in the first region 101 conformally covers the gate structures 130 and the pad spacers 172 with relatively large line widths, and recesses R1 exist between adjacent pad spacers 172. The bottommost end of the recesses R1 are, for example, but not limited to be, lower than the bottom surface of the first pads 160. In this way, the top structures of the gate structures 130 are protected and covered as the second dielectric material layer 174a is formed, so as to further block the first pads 160 and the gate structures 130 from physical contact. On the other hand, the second dielectric material layer 174a formed in the second region 102 just fills the remaining space between adjacent second pads 260, and presents an overall flat top surface. In an embodiment, the first dielectric material layer 172a and the second dielectric material layer 174a preferably include different insulating materials. For example, if the first dielectric material layer 172a includes silicon oxide or silicon oxynitride, the second dielectric material layer 174a includes silicon nitride or silicon carbonitride, but it is not limited thereto.

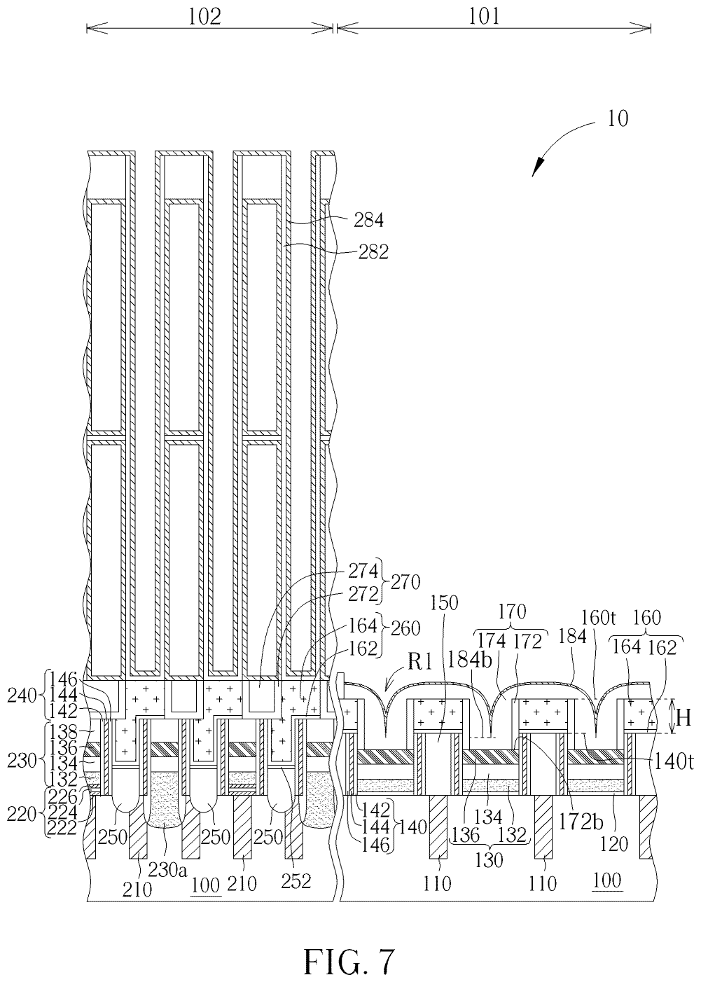

As shown in FIG. 7, a planarization process is performed on the second region 102 of the substrate 100, and the second dielectric material layer 174a and the first dielectric material layer 172a are partially removed. After the planarization process, the second dielectric material layer 174a in the first region 101 forms a covering layer 174, which forms the insulating layer 170 having the recesses R1 together with the pad spacers 172 in the first region 101, and on the other hand, the second dielectric material layer 174a and the first dielectric material layer 172a in the second region 102 form second dielectric layers 274 and first dielectric layers 272 with a U-shaped cross-section, which jointly form the insulating layers 270. The top surfaces of the insulating layers 270 are flush with the top surfaces of the second pads 260.

Subsequently, bottom electrode layers 282 are formed on the insulating layers 270 and the second pads 260 and in physical contact with the top surfaces of the second pads 260. The bottom electrode layers 282, for example, but not limited to, include titanium nitride. Next, a capacitor dielectric layer 284 is formed on the bottom electrode layers 282, and include, for example, a high dielectric constant dielectric material selected from a group consisting of hafnium oxide, hafnium silicon oxide, hafnium silicon oxynitride, zinc oxide, titanium oxide and zirconia-alumina-zirconia, wherein zirconia-alumina-zirconia is preferable. It is to be noted that when the capacitor dielectric layer 284 is formed, the capacitor dielectric layer 284 may extend into the first region 101 to cover on the insulating layer 170. In this way, the capacitor dielectric layer extending into the first region 101 forms the high dielectric constant material layer 184 in the recesses R1, as shown in FIG. 1. The bottommost surfaces 184b of the high dielectric constant material layer 184 are lower than the topmost surfaces 160t of the first pads 160. That is, the high dielectric constant material layer 184 in the first region 101 is a part of the capacitor dielectric layer, which forms the capacitor dielectric layer 284 in the second region 102, and the process of forming the high dielectric constant material layer 184 in the first region 101 can be integrated with the process of forming the capacitor dielectric layer 284 in the second region 102 with the same material.

Subsequently, top electrode layers 28 are formed on the capacitor dielectric layer 284, so that the top electrode layers 286, the capacitor dielectric layer 284 and the bottom electrode layers 282 in the second region 102 together form the capacitor structures 280 as shown in FIG. 1, and the contact structures 190 as shown in FIG. 1 are formed in the first region 101 to produce this embodiment of semiconductor device 10. In the configuration, the vertical capacitors of the capacitor structures 280 and the transistor components (not shown) formed in the second region 102 of the substrate 100 can form minimum memory cells to receive voltage information from the bit lines 130 and the word lines. Thus the semiconductor device 10 in this embodiment can form a dynamic random access memory device and achieve enhanced operational performance.

According to the manufacturing process in this embodiment, by integrating the processes of forming components in the first region 101 and the second region 102 of the substrate 100, the gate structures 130 and the bit lines 230 with relatively large line widths are respectively formed in the first region 101 and the second region 102 by a similar process. Furthermore, by integrating the processes of forming the insulating layer 170 in the first region 101 and the insulating layer 270 in the second region 102 and/or integrating the processes of forming the high dielectric constant material layer 184 in the first region 101 and the capacitor dielectric layer 284 in the second region 102, the top structures of the gate structures 130 are protected with the high dielectric constant material layer 184 and/or the insulating layer 170 formed in the first region 101, thereby avoiding direct contact between the first pads 160 and the gate structures 130 after the cap layers 138 in the first region 101 are removed. Under this operation, the manufacturing process of the semiconductor device in this embodiment can form the semiconductor device 10 with a reliable structure and satisfactory performance based on the simplified manufacturing process.

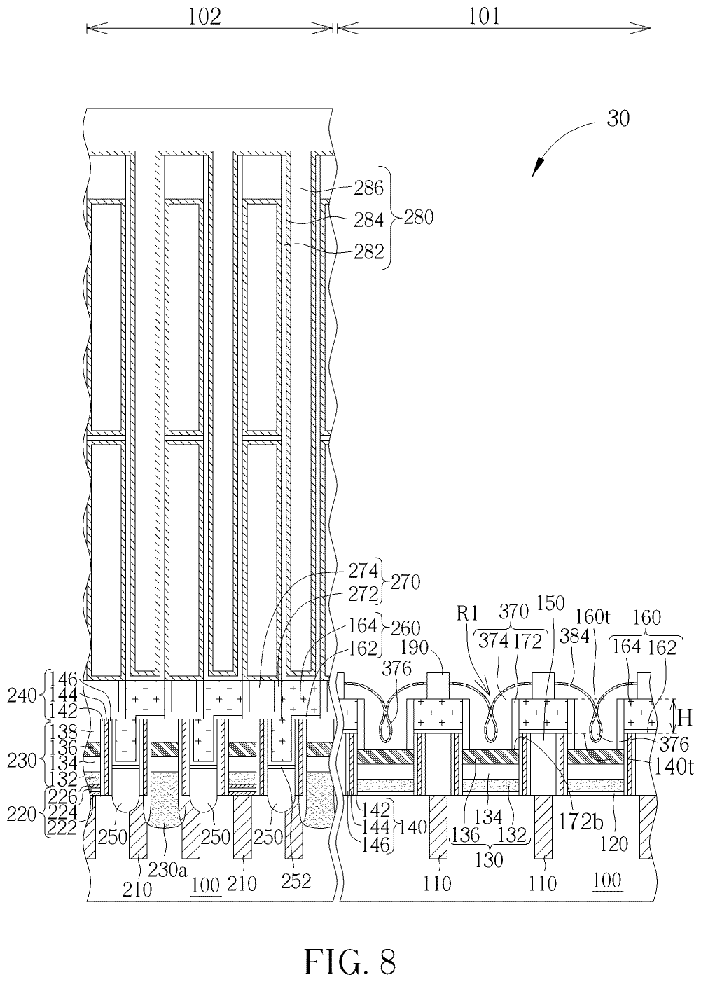

Please refer to FIG. 8, which is a schematic cross-sectional view of a semiconductor device 30 according to a second embodiment of the present invention. The structure of the semiconductor device 30 in this embodiment is basically the same as that of the semiconductor device 10 in the previous embodiment shown in FIG. 1, and the similarities are not repeated herein. The main difference between the semiconductor device 30 in this embodiment and the semiconductor 10 in the above-described embodiment is that a covering layer 374 in this embodiment has voids 376 in lower portions of the recesses R1.

In detail, as shown in FIG. 8, the insulating layer 370 in this embodiment includes pad spacers 172 and the covering layer 374. The covering layer 374 conformally overlies the pad spacers 172, the first pads 160 and the gate structures 130 with a relatively large line width, so that the covering layer 374 includes indentation (not shown) in between adjacent pad spacers 172. It is to be noted that a subsequently formed high dielectric constant material layer 384 further covers and partially closes the indentation, forming the recesses R1 and the voids 376 as shown in FIG. 8, wherein a part of the high dielectric constant material layer 384 is also formed in the voids 376 and in direct contact with the voids 376, but it is not limited thereto.

In the above-described configuration of semiconductor device 30 according to this embodiment, the top structures of the gate structures 130 can also be effectively protected as being covered by the insulating layer 370 and/or the high dielectric constant material layer 384, which ensures that the metal interconnection lines (such as the contact structures 190) disposed in the first region 101 are only electrically connected to the first pads 160 without contact with the gate structures 130. Thus the short-circuit problems possibly encountered in the prior art can be avoided. Therefore, a dynamic random access memory device including this embodiment of semiconductor device 30 can be made with reliable structures and properties and has enhanced operational performance.

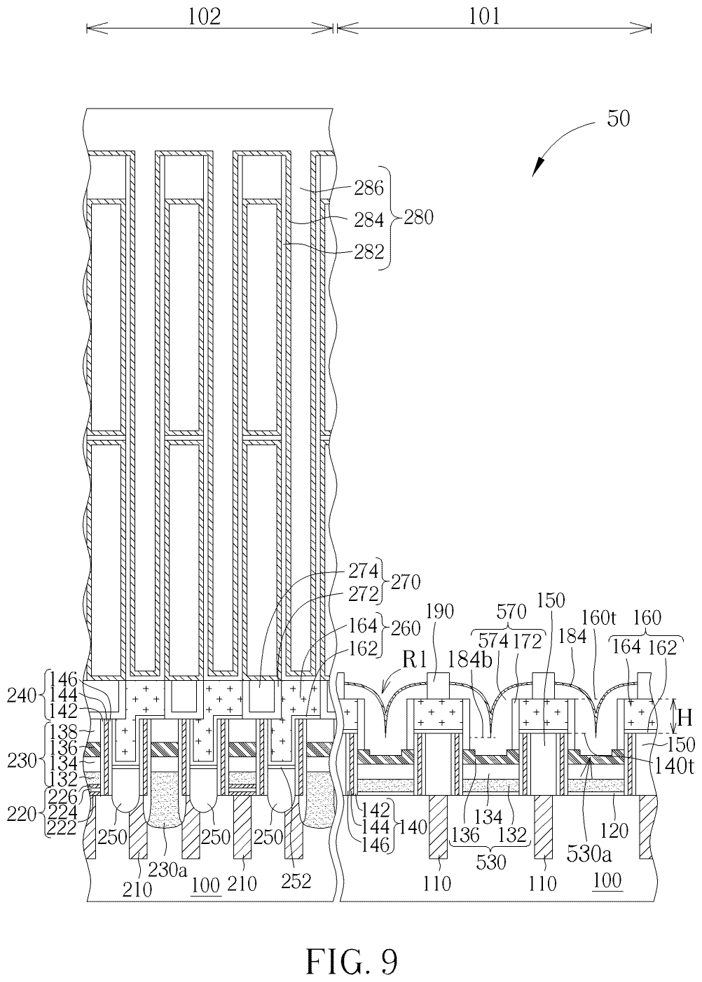

Please refer to FIG. 9, which is a schematic cross-sectional view of a semiconductor device 50 according to a third embodiment of the present invention. The structure of the semiconductor device 50 in this embodiment is basically the same as that of the semiconductor device 10 in the above-described embodiment shown in FIG. 1, so the similarities are not repeated herein. The main difference between this embodiment of semiconductor device 50 and the embodiment of semiconductor device 10 is that gate structures 530 in this embodiment have top depressions 530a, and a covering layer 574 fills the depressions 530a.

In detail, as shown in FIG. 9, the insulating layer 570 in this embodiment includes the pad spacers 172 and the covering layer 574. The covering layer 574 covers the pad spacers 172, the first pads 160 and the gate structures 530, which have a relatively large line width, in a conformal manner. The covering layer 574 includes recesses R1 between adjacent pad spacers 172. It is to be noted that in this embodiment, when the first dielectric material layer 172a located in the first region 101 as shown in FIG. 5 is partially removed, the etching conditions of the etching back process are adjusted to partially remove the metal layers 136 of the gate structures 530, so as to form depressions 530a on the top of the gate structures 530. In this way, the depressions 530a can be formed between adjacent pad spacers 172. Optionally, the sidewalls of the depressions 530a may be vertically aligned with the sidewalls of the pad spacers 172, but it is not limited to thereto. Then, the covering layer 574 formed subsequently is filled into the depressions 530a to cover and protect the top structures of the gate structures 530.

In the above-described configuration of semiconductor device 50 according to this embodiment, the top structures of the gate structures 530 can also be effectively protected as being covered by the insulating layer 570 and/or the high dielectric constant material layer 184, which ensures that the metal interconnection lines (such as the contact structures 190) disposed in the first region 101 are only electrically connected to the first pads 160 without contact with the gate structures 530. Thus the short-circuit problems possibly encountered in the prior art can be avoided. Therefore, a dynamic random access memory device including this embodiment of semiconductor device 50 can be made with reliable structures and properties and has enhanced operational performance.

On the whole, a manufacturing process of a semiconductor device according to the present invention integrates processes of forming components in different regions. Through the simplified manufacturing process, the gate structures can still be effectively protected by blocking the undesired physical contact between the gate structures and the pads with a concave high dielectric constant material layer or lower-bottom pad spacers additionally disposed on the gate structures in the peripheral region. Therefore, defects that might occur in the top structures of the gate structures can be prevented, and short-circuit problems that might occur between the gate structures and the metal interconnection lines disposed thereabove can be avoided.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate;
a gate structure disposed on the substrate;
a plurality of insulating spacers disposed on the substrate and located at opposite sides of the gate structure;
a plurality of first pads disposed on the plurality of insulating spacers;
an insulating layer overlying the plurality of insulating spacers and the gate structure, wherein a portion of the insulating layer overlying the gate structure has a recess; and
a high dielectric constant dielectric layer disposed in the recess, wherein a bottommost surface of the high dielectric constant dielectric layer is lower than a topmost surface of the first pads.

2. The semiconductor device according to claim 1, wherein the insulating layer further comprises:
a plurality of pad spacers disposed on sidewalls of the plurality of first insulating spacers, wherein the recess is disposed between adjacent two of the plurality of pad spacers; and
a covering layer overlying the plurality of pad spacers.

3. The semiconductor device according to claim 2, wherein the covering layer comprises a void under the recess.

4. The semiconductor device according to claim 3, wherein the high dielectric constant dielectric layer covers a surface of the void.

5. The semiconductor device according to claim 2, wherein a top surface of the gate structure has a depression between adjacent two of the pad spacers, and the covering layer is further disposed in the depression.

6. The semiconductor device according to claim 1, further comprising:
a plurality of contact structures disposed on the plurality of first pads; and
a first spacer structure disposed between the gate structure and one of the insulating spacers, wherein a top surface of the first spacer structure is higher than a top surface of the gate structure.

7. The semiconductor device according to claim 1, wherein each of the first pads has a specified height in a direction perpendicular to the substrate, and the bottommost surface of the high dielectric constant dielectric layer is lower than a position that is half the specified height down from the topmost surface of the first pads.

8. The semiconductor device according to claim 1, further comprising:
a plurality of bit lines disposed on the substrate;
a plurality of plugs disposed on the substrate and alternately arranged with the plurality of bit lines;
a plurality of second pads disposed on the plurality of plugs; and
a capacitor structure disposed on the plurality of second pads and comprising a bottom electrode layer, a capacitor dielectric layer and a top electrode layer in sequence, wherein the capacitor dielectric layer and the high dielectric constant dielectric layer comprise a same material.

9. A semiconductor device, comprising:
a substrate defined with a first region and a second region;
a gate structure disposed on the substrate and located in the first region;
a plurality of insulating spacers disposed on the substrate and located at opposite sides of the gate structure;
a first spacer structure disposed on a sidewall of the gate structure and located between the gate structure and one of the insulating spacers;
a plurality of first pads disposed on the plurality of insulating spacers, respectively; and
a plurality of pad spacers disposed on sidewalls of the plurality of first pads, respectively, wherein a bottom surface of the pad spacers is lower than a top surface of the first spacer structure.

10. The semiconductor device according to claim 9, further comprising:
a covering layer disposed on the plurality of pad spacers, the gate structure and the plurality of first pads, wherein the covering layer comprises a recess above the gate structure and between adjacent two of the pad spacers.

11. The semiconductor device according to claim 10, further comprising:
a plurality of bit lines disposed on the substrate and located in the second region;
a plurality of plugs disposed on the substrate and alternately arranged with the plurality of bit lines;
a plurality of second pads disposed on the plurality of plugs; and
a capacitor structure disposed on the plurality of second pads and comprising a bottom electrode layer, a capacitor dielectric layer and a top electrode layer in sequence, wherein at least a part of the capacitor dielectric layer is disposed in the recess.

12. The semiconductor device according to claim 11, wherein a bottommost surface of the part of the capacitor dielectric layer is lower than a topmost surface of the first pads in the first region.

13. The semiconductor device according to claim 11, wherein the covering layer comprises a void under the recess.

14. The semiconductor device according to claim 13, wherein the part of the capacitor dielectric layer covers a surface of the void.

15. The semiconductor device according to claim 11, further comprising:
an insulating layer overlying the plurality of bit lines and comprising a first dielectric layer and a second dielectric layer stacked in sequence, wherein the first dielectric layer and the pad spacers comprise a same material.

16. The semiconductor device according to claim 15, wherein a top surface of the insulating layer is coplanar with a top surface of the second pads.

17. The semiconductor device according to claim 10, further comprising:
a plurality of contact structures disposed on the plurality of first pads.

18. The semiconductor device according to claim 10, wherein a top surface of the gate structure has a depression between adjacent two of the pad spacers, and the covering layer is further disposed in the depression.

19. The semiconductor device according to claim 18, wherein the top surface of the first spacer structure is higher than the top surface of the gate structure.

20. The semiconductor device according to claim 19, further comprising:
a plurality of second spacer structures, each of which is disposed between one of the bit lines and an adjacent one of the plugs, wherein a top surface of the second spacer structures is coplanar with a top surface of the bit lines and higher than the top surface of the first spacer structure.
